(19) United States
(12) Patent Application Publication
(10) Pub. No.: US 2013/0207069 A1
(43) Pub. Date: Aug. 15, 2013

(54) METAL-INSULATOR TRANSITION SWITCHING DEVICES

(71) Applicants: Matthew D. Pickett, San Francisco, CA (US); Philip J. Kuekes, Menlo Park, CA (US); R. Stanley Williams, Portola Valley, CA (US); Frederick Perner, Santa Barbara, CA (US); Wei Wu, Palo Alto, CA (US); Alexandre M. Bratkovski, Menlo Park, CA (US)

(72) Inventors: Matthew D. Pickett, San Francisco, CA (US); Philip J. Kuekes, Menlo Park, CA (US); R. Stanley Williams, Portola Valley, CA (US); Frederick Perner, Santa Barbara, CA (US); Wei Wu, Palo Alto, CA (US); Alexandre M. Bratkovski, Menlo Park, CA (US)

(21) Appl. No.: 13/880,269

(22) PCT Filed: Oct. 21, 2010
(86) PCT No.: PCT/US2010/053549

§ 371 Date: Apr. 18, 2013

(51) Int. Cl. H01L 47/02; H01L 47/00

(52) U.S. Cl. CPC H01L 47/02; H01L 47/005
USPC 257/8; 438/50

(57) ABSTRACT

A metal-insulator transition switching device includes a first electrode and a second electrode. A channel region which includes a bulk metal-insulator transition material separates the first electrode and the second electrode. A method for forming a metal-insulator transition switching device includes depositing a layer of bulk metal-insulator transition material in between a first electrode and a second electrode to form a channel region and forming a gate electrode operatively connected to the channel region.

### BACKGROUND

Devices which control electrical current are widely used in modern technology. For example, semi-conductor transistors are components in practically all modern electronics. Transistors are used to switch, amplify, and condition electrical currents. Current integrated circuits, such as memory and central processors, may include hundreds of millions of transistors. However, silicon based semiconductor transistors have a number of limitations. First, the majority of semiconductor transistors are designed to be implemented on a crystalline silicon surface. These crystalline silicon surfaces are formed by slicing a silicon ingot into wafers. Because of this limitation, semiconductor transistors cannot be easily used on other substrates or in three dimensional circuits. Second, because of their complexity, semiconductor transistors can require a large number of lithograph steps to manufacture. Third, as sizes of conventional semiconductor transistors shrink, the channel widths also become narrower. This dramatically increases the leakage currents through the channel when the transistors are in the OFF state. The leakage currents create a number of problems, including high power consumption, poor ON/OFF ratios, and a large amount of heat which must be dissipated to maintain the operating temperature of the device. The combination of these and other factors can reduce the desirability of semiconductor transistors for a number of applications including nanoscale memristive memory and multilayer circuitry.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1A is a cross-sectional diagram of an illustrative metal-insulator transition switching device, according to one example of principles described herein.

FIG. 1B is a graph showing the switching operation of an illustrative metal-insulator transition switching device, according to one example of principles described herein.

FIG. 2A describes a method for constructing a metal-insulator transition switching device, according to one example of principles described herein.

FIG. 2B is a diagram of the operation of an illustrative metal-insulator transition switching device, according to one example of principles described herein.

FIG. 3A describes a method for constructing an illustrative metal-insulator transition switching device, according to one example of principles described herein.

FIG. 3B is a diagram of the operation of an illustrative metal-insulator transition switching device, according to one example of principles described herein.

FIG. 4A is a plan view of an illustrative metal-insulator transition switching device with a heating element, according to one example of principles described herein.

FIGS. 4B and 4C are cross sectional views of the illustrative metal-insulator transition switching device shown in FIG. 4A, according to one example of principles described herein.

FIGS. 4D through 4F are diagrams of a device that contains a number of metal-insulator transition switching devices, according to one example of principles described herein.

FIG. 5A is a graph showing an illustrative chart of various states of a metal-insulator transition material, according to one example of principles described herein.

FIGS. 5B and 5C are graphs showing illustrative metal-insulator transitions resulting from pressure and temperature changes, according to one example of principles described herein.

FIGS. 6A and 6B are cross sectional diagrams of illustrative metal-insulator transition switching devices which utilize pressure transducers, according to one example of principles described herein.

FIG. 6C is a cross sectional diagram of illustrative metal-insulator transition switching devices which utilizes a combination of pressure and temperature transducers, according to one example of principles described herein.

Throughout the drawings, identical reference numbers designate similar, but not necessarily identical, elements.

### DETAILED DESCRIPTION

Electronic switching in modern devices is primarily performed by transistors. As discussed above, transistors have a number of well known weaknesses which include limited scalability, leakage currents, complex lithography steps, and compatibility with a limited number of substrates.

The present specification describes metal-insulator transition devices which can be created at nanoscales and used to selectively switch electrical currents. The metal-insulator transition devices can be switched using a number of extrinsic variables, including temperature and pressure changes. The devices can be used in a variety of applications, including multilayer circuits and applications which use silicon based transistors. In some examples, the metal-insulator transition devices may have activation energies which are comparable to many transistors. The metal-insulator transition devices may be created using fewer steps and have a smaller foot print than conventional transistors. The metal-insulator transition devices can also be formed on a variety of substrates. This allows the devices to be used in a variety of applications inaccessible to conventional Complimentary Metal Oxide Silicon (CMOS) devices, such as stacked and flexible circuits.

The metal-insulator transition devices have no physical scaling limit because the metal-insulator transition is based on a bulk effect. As used in the specification and appended claims, the term “bulk” refers to a fundamental characteristic of a material which is present throughout the volume of the material. Consequently, a bulk effect in a material has no scaling limit because the bulk effect is a fundamental characteristic of the material itself. Any size portion of the material will exhibit the bulk effect. This is in direct contrast to devices which depend on the addition of dopants, impurities, or the motion of dopants. These devices do not operate on bulk effects and are limited to sizes which can be reliably doped.

The metal-insulator transition materials and effects described herein are bulk materials and bulk effects. The metal-insulator transition devices have no scaling limit because the metal-insulator transition is a characteristic of the material itself. Examples of bulk metal-insulator transition materials include, but are not limited to, transition metal oxides and perovskite. The metal-insulator transition materials, devices, and effects discussed herein are not dependant on the addition of small numbers of dopants, dopant concentration changes, the motion of dopants, or other changes in the composition of the material.

In some examples, properties of a metal-insulator device will improve as the device is reduced in size. For example, as the volume of the device decreases, the switching energy and power dissipation also decrease. Further, the nanoscale metal-insulator transition devices have very high resistivity in the OFF state. This can result in negligible leakage currents, low power consumption, and reduced heat loads. In its conductive or ON state, the nanoscale metal-insulator transition device may have a resistance which several orders of magnitude lower than the resistance of the OFF state. This allows for a clear distinction between the ON/OFF states of the metal-insulator transition devices.

Additionally, the small size of the metal-insulator transition devices dramatically increases their switching speed. For example, in a temperature switched metal-insulator device, the speed of heat diffusion is directly related to the square of the diffusion distance. For atomic scale distances, the speed of diffusion is on the order of speed of sound through the material. For example, a solid material may exhibit a speed of sound of approximately 1000 m/s or about one nanometer per picosecond. Consequently, a thermally switched metal-insulator transition device may have length scales on the order of tens of nanometers and switching speeds on the order of tens of picoseconds.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

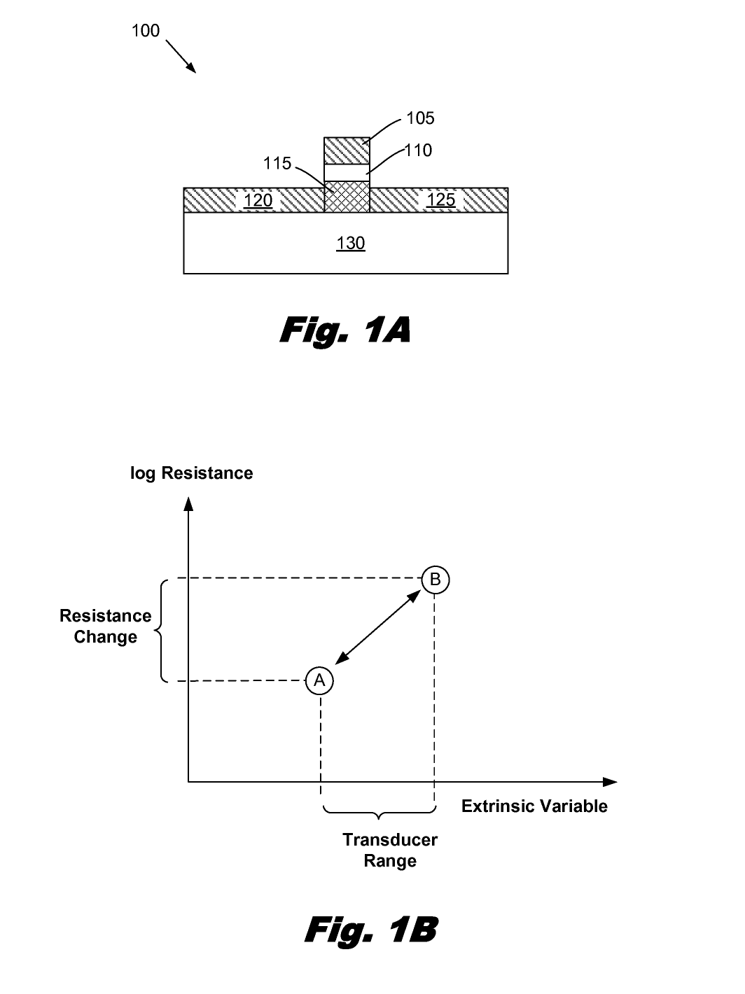

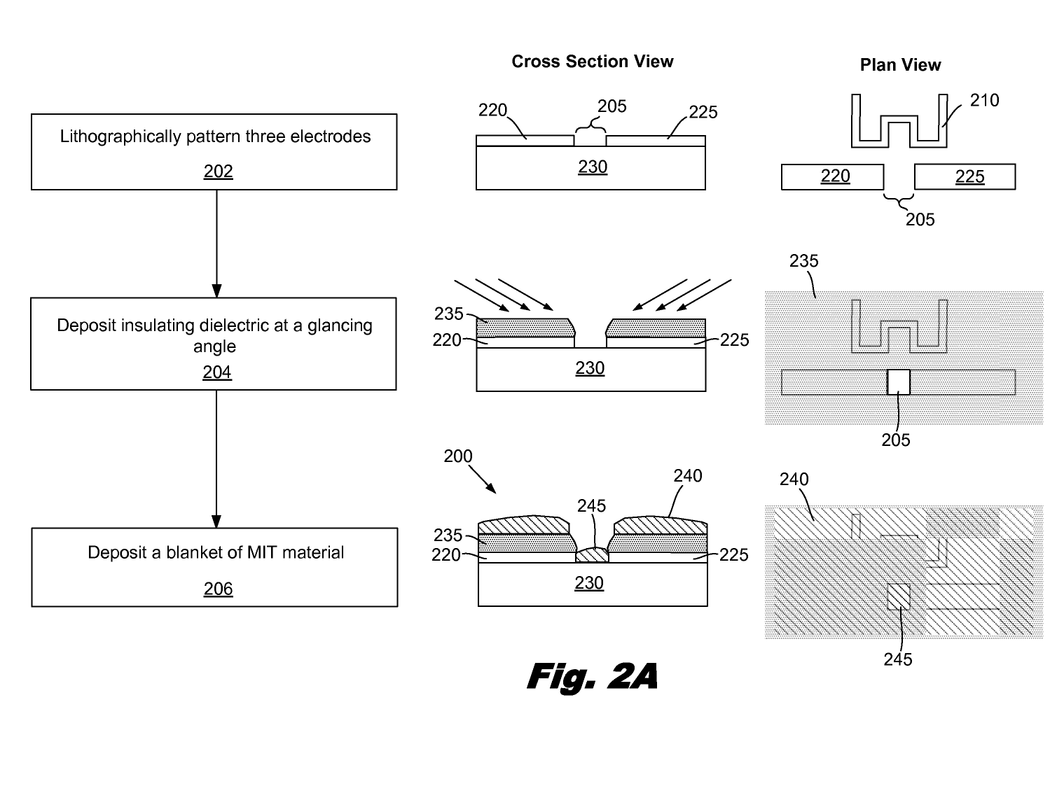

FIG. 1A is an illustrative cross-sectional diagram of a metal-insulator transition (MIT) switching device (100). The MIT switching device (100) includes a gate electrode (105) and an extrinsic variable transducer (110) which are placed over the MIT channel (115). A left electrode (120) and a right electrode (125) are formed on either side of the MIT channel (115). The MIT channel (115) may have two distinct states: an insulating state and a metallic state. As used in the specification and appended claims, the term “metallic state” is used to indicate a condition in which a MIT material exhibits metal-like electrical conductivity. The use of the term “metallic state” does not indicate that the MIT channel has changed into a metal. When the MIT channel (115) is in an insulating state, the left electrode (120) is electrically isolated from the right electrode (125). When the MIT channel (115) is in a metallic state, it creates an electrically conductive bridge between the left electrode (120) and the right electrode (125).

In one example, the gate electrode (105) may be electrically activated to change the state of the MIT channel (115). This controls the extrinsic variable transducer (110) which converts the electrical energy into an extrinsic variable which influences the transition of the MIT channel (115) between its insulating and metallic states. As used in the specification and appended claims, the term “extrinsic variable” refers to an external stimulus which influences the metal-insulator transition of an MIT material. The transition of the MIT material between an electrical insulator and an electrical conductor can be a very sharp function of the extrinsic variable. For example, a change of a few degrees in the temperature of the channel can result in a change in the electrical resistance of several orders of magnitude. Temperature changes of tens of degrees can result in increases of four to six orders of magnitude. The transition temperature and the sharpness of transition may be influenced by a variety of factors, including the type of MIT material, number of defects in the MIT material and the degree of crystallinity of the MIT material. In general, the more crystalline the MIT material, the sharper the transition between the metallic and insulator states. These large changes in resistance of the MIT channel (115) act as a switch between the left electrode (120) and the right electrode (125). The behavior of this switch may be controlled by the activation of the gate electrode (105).

As discussed above this MIT switching device (100) could have a number of advantages including simplicity of operation and construction, small size, low power requirements, and the ability to be readily integrated into a number of different electronic devices.

FIG. 1B shows a graph demonstrating the operation of the MIT switching device (100). On the horizontal axis, the values for an extrinsic variable are shown. On the vertical axis, the resistance change of the MIT channel (115) is shown, with low resistances being shown lower on the vertical axis and higher resistances being shown correspondingly higher on the vertical axis. For convenience, the scale of the vertical axis is in log notation. As the transducer influences the extrinsic variable over a range, the state of the MIT channel changes from state A to state B. This results in a corresponding resistance change in the MIT Channel. The resistance change between an ON and OFF state may be approximately four to six orders of magnitude, depending on the MIT material type, crystallinity, amount of change in the extrinsic variable, and other factors. Even a change in resistance of one order of magnitude may be useful in some applications. Consequently, the change in resistance is significant and measurable between the left electrode (120) and the right electrode (125). The extrinsic variable may be any one of a number of variables, including pressure, temperature, magnetic field, electric field, or other variables.

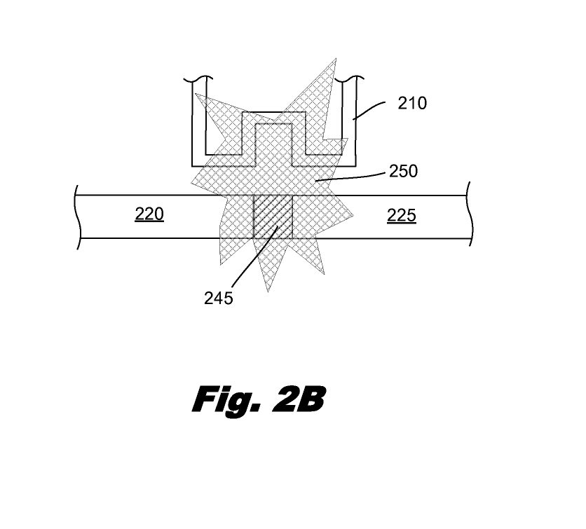

FIG. 2A shows an illustrative method for forming an MIT switching device (200). In a first block (202), the three electrodes (210, 220, 225) are lithographically patterned on a substrate (230). At this point, each of the three electrodes (210, 220, 225) are electrically isolated from each other. In particular, the left electrode (220) and the right electrode (225) are separated by a gap (205). The heater electrode (210) is positioned to one side of the left electrode (220) and the right electrode (225). These electrodes (210, 220, 225) may be formed in a variety of ways including high density copper damascene techniques. As used in the specification, the term “copper damascene” is used broadly to describe a process to define a metal conductor by filling a trench in a dielectric with conductor material and isolating the conductor regions with a chemical mechanical polish planarization process. The width of the metal conductor defines the width of the active portion of the MIT switching device (200).

In a second block (204), an insulating dielectric layer (235) may be deposited over the three electrodes (210, 220, 225) and substrate (230). In one embodiment, the insulating dielectric may be deposited at two opposing glancing angles so that the dielectric layer (235) is not deposited in the gap (205).

The third block (206) illustrates the deposition of a blanket of MIT material (240) which covers the upper surfaces and fills the gap between the first electrode and the second electrode. For example, the MIT material may be a transition metal oxide. Transition metals are the 38 elements in groups 3 through 12 of the periodic table and include titanium, tantalum, vanadium, chromium, manganese, and other metals. One example of a transition metal oxide is vanadium oxide. At temperatures below approximately 60-70 C, crystalline forms of VO₂ may exhibit a monoclinic crystalline structure which is electrically insulating. At temperatures above approximately 60-70 C, the crystalline structure of the VO₂ may change to a tetragonal form which is electrically conductive.

A portion of this MIT material (240) is deposited into the gap (205) between the left electrode (220) and the right electrode (225) to form a MIT channel (245). This MIT channel (245) then forms the switch between the left electrode (220) and the right electrode (225). The state of the MIT Channel (245) is influenced by electrical current passing through the heater electrode (210).

As shown in FIG. 2B, as an electrical current is passed through the heater electrode (210) it creates a heat-affected zone (250) which encompasses the MIT channel material (245). As the MIT channel (245) changes temperature, its state is altered from an insulating state to a metallic state. In its metallic state, the MIT channel (245) readily conducts electrical current from the left electrode (220) to the right electrode (224), or vice-versa.

The heater electrode (210) may have a variety of configurations which produce localized heat generation in proximity to the MIT channel. As illustrated in FIG. 2B, a portion of the heater electrode may be serpentine. The longer serpentine portion concentrates the heat generated near the MIT channel (245). In other embodiments, the heater electrode (210) could have a reduced cross sectional area portion or portions. The reduced cross sectional portions have a higher electrical resistance. The reduced cross sectional portion can be located in proximity to the MIT channel. When a current is passed through the heater electrode, the higher resistance of the reduced cross section portions can generate localized heating which changes the state of the MIT channel.

In other examples, the heater electrode may be formed from two different materials. A first material may be highly conductive and form the wiring which routes electrical currents. A second material is more resistive and is placed near the MIT channel. For example, the first material may be copper or gold and the second material may be tungsten. As the electrical current passes through the heater electrode, the copper traces efficiently conduct the electrical current to the tungsten portion with minimal losses. The tungsten portion heats up as the current passes through it. This heat changes the state of the MIT channel.

In many embodiments, the MIT switching device (200) may be a nano-scale device. There are a number of advantages to making the MIT switching device very small. First, the heat is very quickly transmitted over nano-scale distances between the heater electrode (210) and the MIT channel (245). In general, thermal diffusion is viewed as a slow process. However, diffusion speed scales as the square of the diffusion distance. Consequently, for millimeter scale applications, the switching speed of a MIT switching device (200) can be relatively slow. However, where the size of the MIT switching device (200) is on the nanometer scale, the diffusion speed approaches the speed of sound in the material. A conservative estimate of the diffusion speed over nanodistances in typical materials is approximately 1000 meters/second. This is equal to one nanometer per picosecond. Consequently, the heat generated by the gate electrode/heater (210) is very rapidly transmitted over the few nanometers, perhaps tens of nanometers, to the MIT channel material (245). These rapid thermal diffusion speeds allow the MIT switching device (200) to rapidly increase in temperature when the heater is on and rapidly dissipate heat when the heater is off. As a result, in nanoscale MIT switching devices (200), the switching speed can be very rapid and is not typically the limiting factor in the overall speed of the device. For example, the capacitance and inductance of interconnection lines which connect the device to control circuitry can determine the switching speed of the device to a greater degree than the thermal diffusion. Specifically, the resistance/capacitance (RC) time constant of the interconnection lines may be substantially greater than the thermal diffusion times within the switching device.

A second advantage to constructing the nanoscale MIT switching devices (200) is a large reduction in the amount of heat which is required to change the temperature of the MIT channel (245). When constructed at nanoscale dimensions, the volume of the MIT switching device (200), and particularly the MIT channel (245), is very small, on the order of tens to hundreds of cubic nanometers. This low thermal mass allows for the temperature of the MIT channel (245) to be changed by very small additions of heat from the gate electrode/heater (210). Consequently, on a nano-scale, the switching speed and switching energy of the MIT switching device (200) are comparable to conventional devices and are particularly favorable when compared to transistor devices.

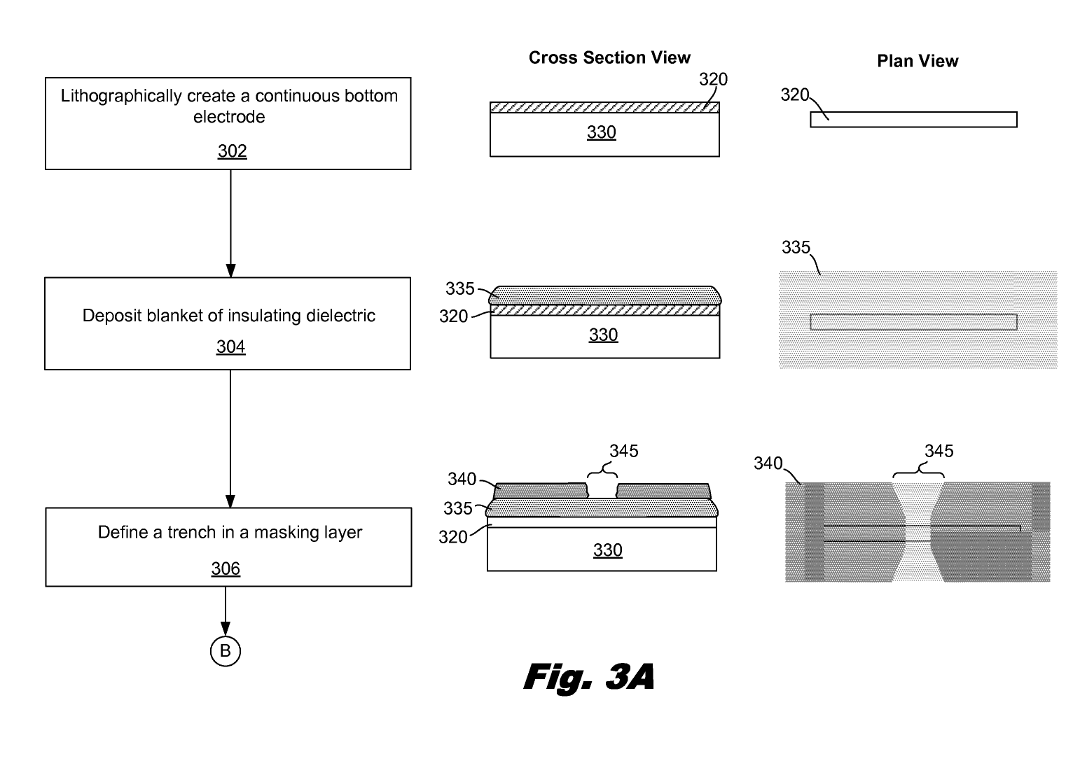

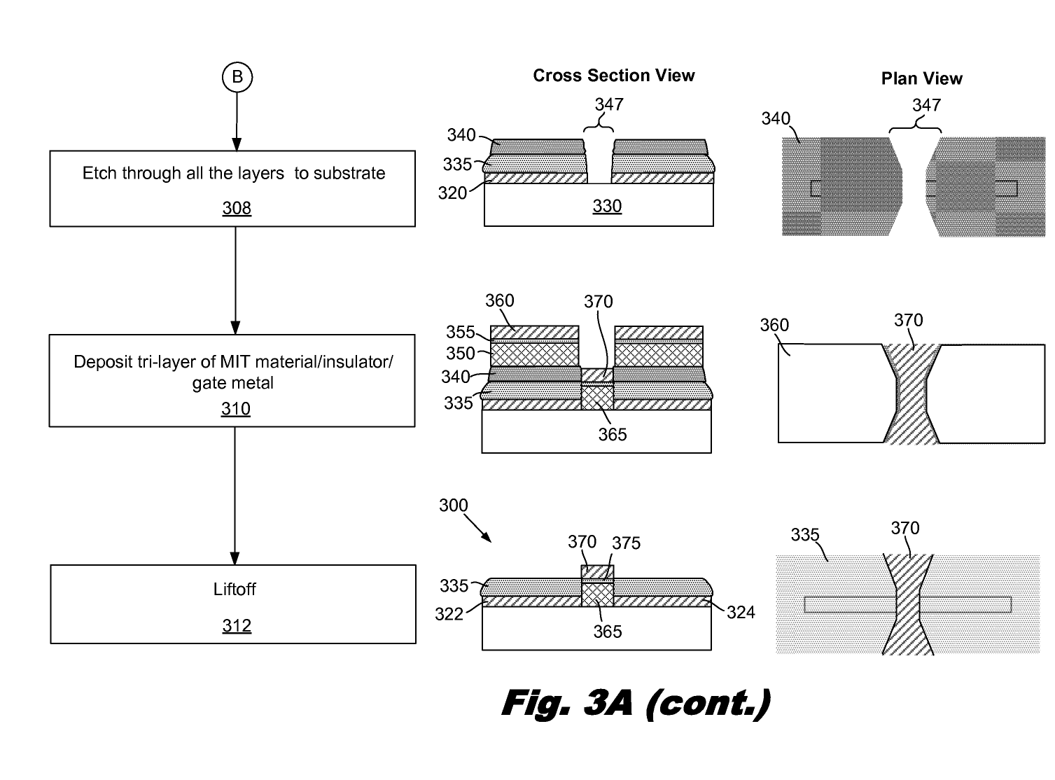

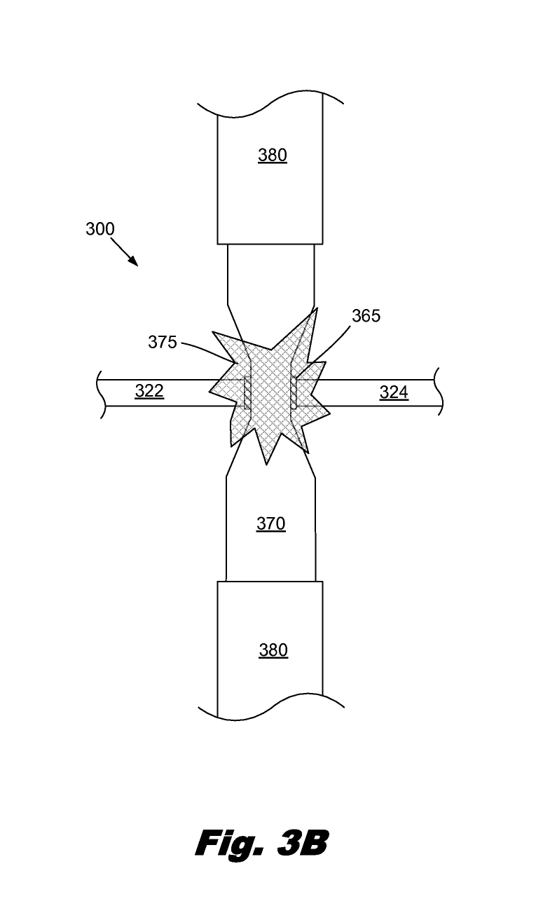

FIG. 3A describes an illustrative method for forming an MIT switching device (300). In the first block (302), a continuous bottom electrode (320) is lithographically created on a substrate (330). In a second block (304), a blanket of insulating dielectric material (335) is deposited over the entire surface. In the third block (306), a trench is lithographically defined by patterning a mask material (340). According to one illustrative embodiment, the mask layer (340) is spin deposited over the surface of the substrate (330) and insulating dielectric layer (335). The trenches (345) are then defined in the mask material (340) using nano-imprint technology, lithography or other suitable techniques.

In a next block (308) an etching process is used to etch through all of the layers including the dielectric blanket (335) and the bottom electrode (320). This creates an etched trench (347) which extends from the upper surface of the assembly to the substrate (330). This etching process may be performed in a variety of ways including, wet etching, plasma etching, or other methods. In a fifth block (310) a tri-layer of MIT material (350), insulator material (355) and gate metal (360) are deposited over the etched assembly. The majority of this tri-layer (350, 355, 360) is deposited onto the mask material (340). However, a small portion of the tri-layer materials is deposited into the etched trench (347). The portions of the tri-layer material that are deposited into the etched trench (347) become the MIT channel (365), an insulating layer (375), and the gate electrode (370). In a final block (312), the tri-layer (350, 355, 360) and mask layer (340) are lifted off the assembly to leave the completed MIT switching device (300). According to one illustrative embodiment, the lift-off process involves chemically dissolving the mask material (340). This allows the portions of the tri-layer materials (350, 355, 360), which were deposited over the mask material (340), to be easily removed. In its final configuration, the MIT switching device is in a crossbar configuration with the MIT channel (365) being interposed between a left electrode (322) and a right electrode (324). Overlying the MIT channel (365) is a thin layer of insulating dielectric (375) and the gate electrode (370). According to one example, the gate electrode (370) may have a tapered cross-section which reaches a minimum width as it passes over the channel material (365). The small cross-sectional area of the gate electrode (370) has a higher electrical resistance than other portions of the gate electrode (370). Consequently, a concentrated amount of heat can be produced throughout the narrow cross-section. Additionally or alternatively, the gate electrode (370) may be formed from tungsten which has a relatively high electrical resistance. As the tungsten gate electrode (370) moves away from the MIT switching device (300), the cross-sectional area of the electrode increases and possibly transitions from tungsten to a copper conductor.

FIG. 3B shows a plan view of the operation of the MIT switching device (300). As described previously, the MIT switching device (300) includes a left electrode (322), a right electrode (324), and a MIT Channel (365) interposed between the left and right electrodes (322, 324). Overlying the MIT channel material (365) is the gate electrode (370). As discussed above, the gate electrode (370) reaches a minimum width over the channel material (365). The gate electrode (370) may be made from a variety of materials, including a combination of highly conductive materials and comparatively resistive materials. For example, the gate electrode (370) may be formed from tungsten, which has a relatively high electrical resistivity compared to other metallic compounds and elements. Consequently, the tungsten electrode (370) forms a very effective heater. In this embodiment, the width of the tungsten has been reduced over the channel material (365) to further concentrate the heat generation. However, tungsten may not be as suitable for transmitting an electric current over long distances as other materials. Consequently, copper or other more conductive leads (380) can be attached to either end of the tungsten gate electrode (370). As an electric current is passed through the tungsten gate electrode (370), it forms a heat affected zone (375). Inside the heat affected zone (375), materials are heated above a transition temperature between the insulating and metallic states of the MIT channel material (365). Consequently, by passing electrical current through the tungsten electrode, the conductive state of the channel material (365) can be altered, thereby selectively electrically connecting the left electrode (322) and the right electrode (324). As discussed above, the MIT channel (365) may be formed from a variety of materials which exhibit a metal-insulator transition.

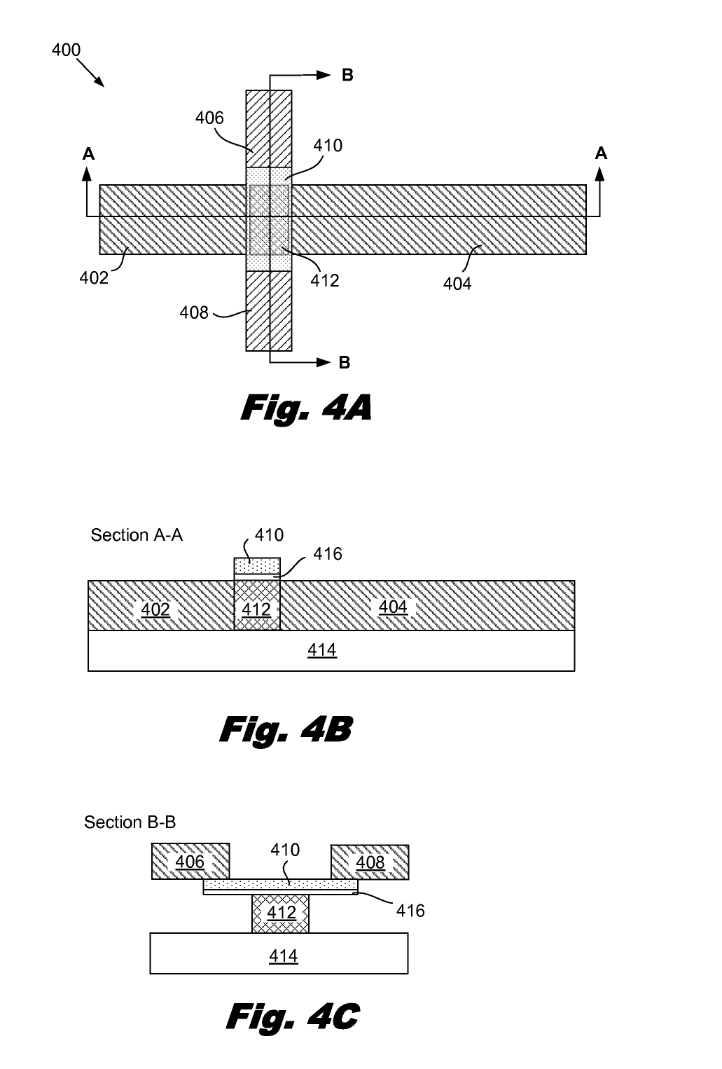

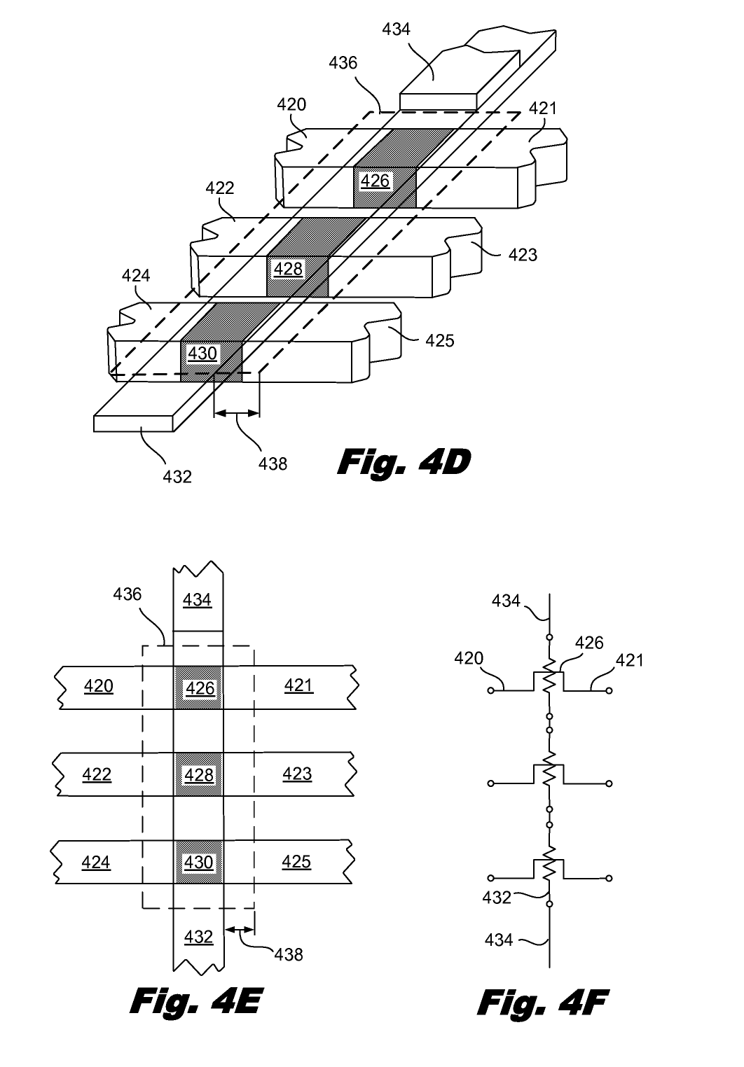

FIGS. 4A through 4C show a MIT switching device which is also in a crossbar configuration. FIG. 4A shows a plan view of this MIT switching device (400). FIG. 4B shows a cross-section taken along the line A-A. FIG. 4C shows a cross-section taken along the section line B-B. In this MIT switching device (400), an MIT channel (412) is interposed between a left electrode (402) and a right electrode (404). A gate assembly (406, 408, 410, 416) intersects the left and right electrodes (402, 404) over the MIT Channel (412). The gate assembly includes a first portion of the gate electrode (406), second portion of the gate electrode (408), and a heater element (410) interposed between the two gate electrodes (406, 408).

As shown in FIG. 4B, the heater element (410) is insulated from the MIT channel (412) by a thin dielectric layer (416). The entire assembly is supported by a substrate (414). The substrate (414) serves a variety of purposes, including providing mechanical support to the overlying structures. The substrate (414) also may serve as a heat-sink which pulls heat out of the MIT channel (412). Heat can be rapidly input into the MIT channel (412) by passing an electrical current through the heater element (410). As discussed above, this changes the MIT channel (412) from an insulating state to a metallic state and allows an electrical current to flow between the two electrodes (402 and 404). However, to rapidly revert the MIT channel (412) to an insulating state the heat which was initially generated by the heater element (410) has to be dissipated. This lowers the temperature of the MIT channel material (412) so that it transitions back into an insulating state. The substrate (414) represents a convenient cooling plane or heat-rejection reservoir into which the heat can be dissipated. In some embodiments, the substrate (414) may be specifically designed to serve as a cooling plane. This may involve actively or passively cooling the substrate and/or including materials in the substrate (414) to spread and conduct heat away from the MIT channel (412).

FIG. 4C shows a cross-section along the section line B-B. In this example, the gate electrode (406, 408) is separated into two portions which are in electrical contact with the heater element (410). In this example, the heater element (410) is formed in a separate layer and the two portions of the gate electrode (406, 408) are patterned in an overlying layer.

The structure described in FIGS. 4A-4C may be formed by a self aligning process that uses a combination of conventional lithography and nanoimprint technology to form a nanoscale MIT switching device. The self aligned MIT is physically defined by processing a second level gate control conductor on top of an orthogonal first level conductor. The steps used to process the second level gate control conductor employ a sequence of etch and deposition steps to bisect the first level conductor and self align the conducting channel to the second level conductor.

The first level conductors (402, 404) can be formed using a high density copper damascene process. The width of the conductors (402, 404) defines the width of the active MIT channel (412) of the device. A layer of dielectric material is then deposited and patterned with trenches. The width of the trenches defines the length of the active MIT channel (412) of the switching devices. Through the dielectric trenches, a vertical etch is performed to the substrate (414). The etch cuts the first metal lines where they are intersected by the trenches to form left and right electrodes (402, 404) which are separated by a gap. This self aligned process cleanly defines both the boundaries of the MIT channel and the electrodes of the device. In one example, vandium oxide, titanium oxide, or other MIT material is uniformly deposited over the wafer. Portions of the MIT material are deposited into the gaps formed in the first level conductors. The MIT material is in electrical contact with exposed ends of the first level metal conductors and forms the MIT channel (412). Chemical-mechanical polishing can then be used to planarize and remove the surface MIT material. Alternatively, a vertical etch can be used to remove the surface MIT material down to roughly level with the top of the first level metal conductors (402, 404).

A thin layer of dielectric is then deposited uniformly over the wafer. This places an insulating layer (416) between the MIT material and the heater conductor formed in the next step. The second level metal is deposited as two layers, a high resistance layer and a low resistance layer. The high resistance layer may be formed from tungsten, a tungsten alloy, or a platinum alloy. The low resistance layer may be formed from copper. The metal layers are then planarized to define the second level metal interconnect.

A photo masking and etch step is used to remove the low resistance copper from the area above the active MIT region. A generous overlap can be used in this non-critical masking layer to define the high resistance heater region. The high resistance heater region mask opens an etch window over the second level conductor and the mask may overlap adjacent dielectric with no effect. The overlap of the adjacent dielectric can be greater than the alignment tolerance to the extent that the heater mask of one MIT device may be merged with the heater masks of adjacent MIT devices as part of groups of MIT devices. A vertical etch is then used to remove the low resistance Cu from the high resistance heater region. Where the MIT switching device is used in a multilayer circuit, the second level of metal may be part of interlevel via routing and connections.

This self aligned process allows the MIT switching device to be fabricated in compliance with high density nano-technology design rules and within the limitations of lithographic processes. The self aligning process eliminates the time consuming and expensive photolithography issues of patterning gaps in lines and patterning a heater structure close to the MIT active region. Low gate interconnect resistance is achieved by using a less critical area mask to open the area above the MIT active region and remove the low resistance conductor material. This leaves only the high resistance gate heater material as the over the MIT channel region.

FIGS. 4D-4F are diagrams of an array of metal-insulator transition switching devices which were fabricated following the self aligning procedure described above. FIGS. 4D and 4E show perspective and plan views, respectively of the metal-insulator transition switching devices. To form the metal-insulator transition switching devices, a trench was etched through three first level conductors to form left electrodes (420, 422, 424) and right electrodes (421, 423, 425). MIT material was placed in the gaps between the left electrodes and right electrodes to form the MIT channels (426, 428, 430). The second level metal is deposited as two layers, a high resistance layer (432) and a low resistance layer (434). A photo masking step is used to remove the low resistance layer (434) from the area above the MIT channels (426, 428, 430). The outline of the photomask area is shown as a dashed rectangle (436). A generous overlap (438) can be used in this non-critical masking layer to define the high resistance heater region over the MIT channels (426, 428, 430). The amount of overlap (438) between the photomask area and the MIT channels can be determined by the mask alignment tolerances.

FIG. 4F is an illustrative schematic diagram of the three switch assembly illustrated in FIGS. 4D and 4E. The low resistance leads (434) are connected to a central high resistance lead (432) which crosses all three MIT channels. The heating action of the high resistance layer (432) is schematically represented as using a resistor symbol. The MIT switching channel (426) is illustrated as a raised line which is between a left and a right electrode (420, 421). Thus, each thermally switched MIT device can be represented as a four terminal device, with a resistive element overlaying a MIT channel. In this example, the control gates of the three MIT devices are arranged in series and are turned on and off together by controlling the electrical current which is passed through the high resistance layer (432). The embodiments described above are only illustrative examples. The MIT switching devices can be used in a variety of circuits, configurations, and be combined with a wide range of other electrical devices to perform a desired function.

FIGS. 2A-2B, FIGS. 3A-3B, and FIGS. 4A-4F all illustrate MIT switching devices which are thermally actuated by resistance heating. However, the gate electrodes and transducer may have a variety of other configurations and can influence the state of the MIT channel by controlling other extrinsic variables.

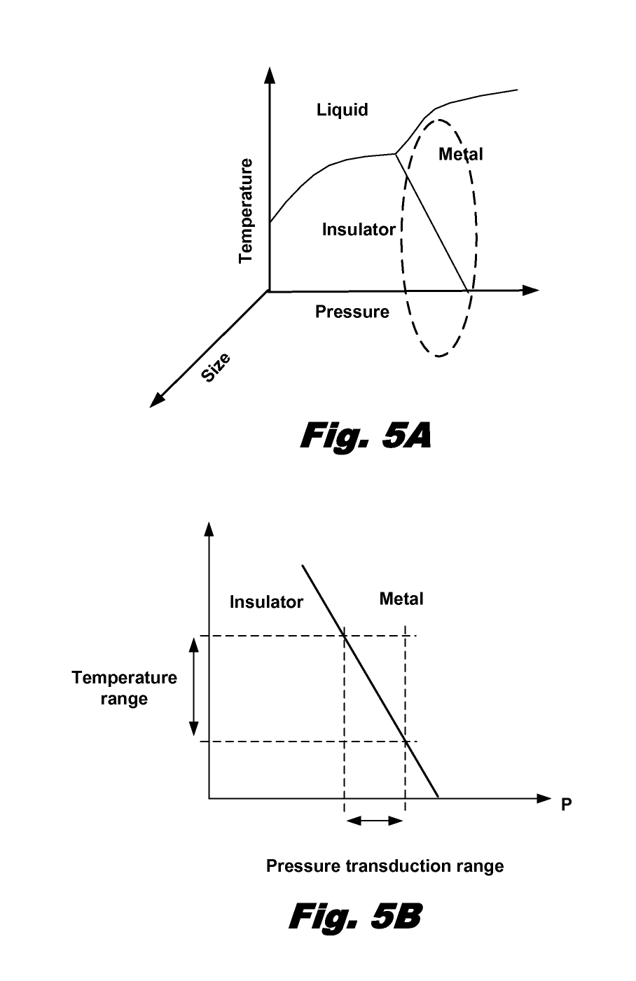

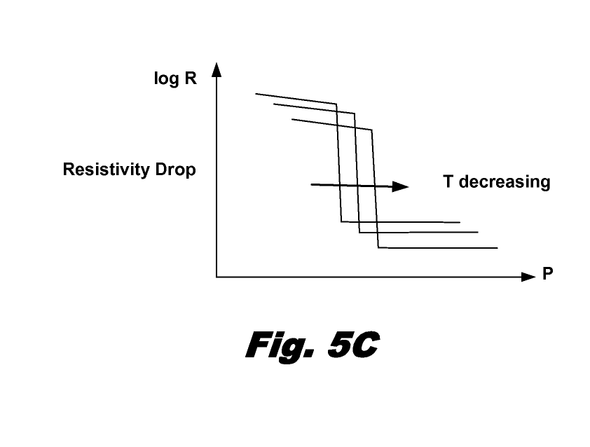

FIG. 5A is a graph which describes an illustrative interrelationship between temperature, pressure, and the state of the MIT material. The three-dimensional graph has a horizontal axis which describes the influence of pressure on the state of the MIT material, a vertical axis which describes the influence of temperature on the MIT material, and a third axis which describes the influence of size of the MIT channel on its operation. As discussed above, the operating regime of the MIT channel occurs between an insulator and a metal state. The transition between the insulator and metal state is indicated by the dashed ellipse in FIG. 5A. As shown in the graph, this illustrative MIT material may transition from the insulator to metallic state under the influence of temperature and/or pressure.

FIG. 5B shows a graph of the portion of the chart shown in FIG. 5A which is encircled by the dotted ellipse. As shown in FIG. 5B, a change in temperature produced by the transducer may transition an MIT material from an insulator to metallic state or vice versa. Dashed lines show the ranges of pressure and temperature changes in the MIT material that are produced by electrically activating transducers. The dashed box formed by the intersection of lines illustrates the range of MIT states that pressures and/or temperatures in the ranges can produce. Consequently, it is clear that the MIT material may be induced to change from an insulator state to a metallic state by changes in pressure alone, change in temperature alone, or a combination of changes in both pressure and temperature.

FIG. 5C shows the resistivity drop as a function of temperature and pressure. The horizontal axis of the graph shown in FIG. 5C indicates increasing pressures, with lower pressures being near the origin of the graph and higher pressures being to the right. The resistivity change is shown on the vertical axis in a logarithmic scale with lower resistances being closer to the origin of the graph and higher resistances being vertically and correspondingly higher on the vertical axis. As shown on the graph in FIG. 5C, increasing pressures cause a transition in the MIT channel from a highly resistive state to a much lower resistance metallic state. As the temperature decreases, the higher pressures are required to make the transition between the insulating and metallic state. This is illustrated by the multiple lines in FIG. 5C, which progressively move toward the right as the temperature decreases. Each line in the graph represents a different temperature, with the lines on the left having a higher temperature and the lines on the right having the lower temperature. Consequently, it is clear that transitions between the insulating and metallic states of a MIT material may be influenced by both temperature and pressure. In other embodiments, some MIT materials may also be influenced by other extrinsic variables such as magnetic fields or other variables.

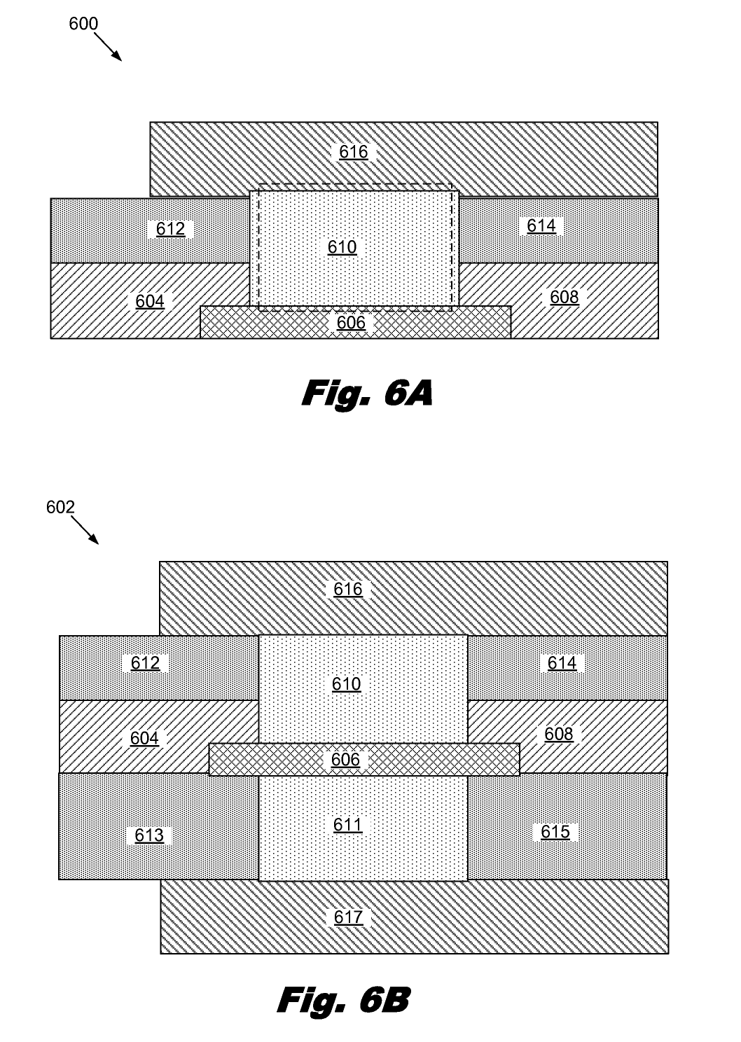

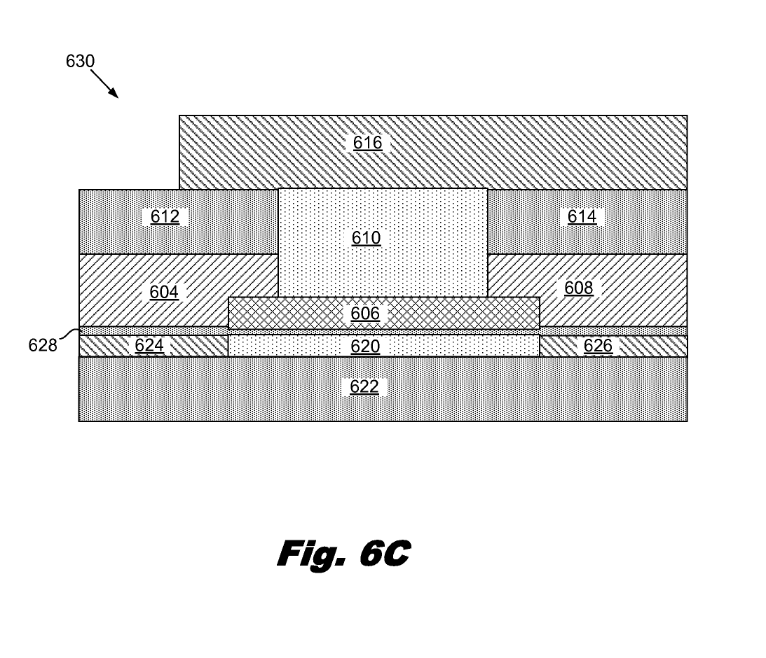

FIGS. 6A and 6B illustrate a transducer which changes the pressure of an MIT channel material (606). In FIG. 6A, the MIT channel material (606) is interposed between a left electrode (604) and a right electrode (608). A piece of piezo electrical material (610) is placed over the MIT channel material (606). A gate electrode (616) is insulated from the underlying left and right electrodes (604, 608) by an insulating layer (612, 614). Electrical activation of the gate electrode (616) and another corresponding electrode (which may be one of the left or right electrodes, or a separate electrode) can produce an electrical field through the piece of piezo electrical material (610). Under the influence of the electrical field, the piece of piezo electrical material (610) changes its geometric shape as shown by the dashed rectangle. This dimensional change creates pressure on the underlying MIT channel (606) and changes its state from an insulating to a metallic state. When the MIT channel (606) is in its metallic state, electrical current can flow from the left electrode (604) to the right electrode (608) or vice versa.

FIG. 6B shows a similar configuration where pressure is used to change the conductive state of the MIT channel material (606). In this configuration, the piezo electric transducers (610, 611) are placed both above and below the MIT channel material (606). The piezo electric transducers (610, 611) are actuated by a gate electrode (616) and counter-gate electrode (617). An electric field is generated by placing a voltage difference across the gate electrode (616) and the counter gate electrode (617). This electrical field controls electro-mechanical transducers (610, 611). A wide range of electro-mechanical transducers may be used including, but not limited to, lead zirconate titanate (PZT) transducers. The counter gate electrode (617) is isolated from the left and right electrodes (604, 608) by insulating regions (613, 615). The configuration in FIG. 6B may have a number of advantages over the example shown in FIG. 6A. These advantages may include greater compressive force being exerted on the MIT channel material (606) and lower deflections of the MIT channel material (606) due to the balanced forces exerted by the upper and lower piezo electric transducers (610, 611).

Although FIGS. 6A and 6B show pressure actuators which exert a uniaxial stress on the MIT channel material (606), a variety of other configurations could be used. In general, the state of the MIT material (606) can be altered by pressure or stress from any direction or combination of directions. Consequently the pressure actuators may be configured in a variety of geometries. For example, a piezoelectric actuator may have a “U” shaped cross-section, with the MIT channel in the center. The “U” shaped piezoelectric actuator may then exert pressure on the MIT channel in several different directions.

In the layout of MIT switching devices, a number of factors could be considered. These factors may include reducing cross talk between adjacent MIT switching devices. Where the MIT device is switched using thermal energy, that thermal energy would ideally be dissipated before reaching other MIT switching devices which are horizontally or vertically adjacent to the target switch. This will prevent the unintentional activation of the surrounding switches. Similarly, where pressure actuators are used, the stress fields produced by the pressure actuators would ideally be concentrated in and around the target MIT device to prevent unintentional activation of the surrounding MIT devices. The requisite level of isolation between adjacent devices can be accomplished in a number of ways, including interposing material between the switches, altering the spacing of switches in a given plane, or altering the relative location of switches in adjacent layers of a multilayer circuit.

FIG. 6C shows an example of an MIT switching device (630) which incorporates both pressure and temperature as extrinsic variables which influence the state of the MIT channel material (606). The upper layers (604, 606, 608, 610, 612, 614, 616) of the MIT switching device (630) are identical to the layers shown in FIG. 6A. However, the lower layers (620, 622, 624, 626, 628) incorporate an electrical heater (620) which is connected to two heater electrodes (624, 626). By passing electrical current through the heater electrodes (624, 626), the heater (620) rapidly generates thermal energy which changes the temperature of the MIT channel material (606).

In one example, both pressure and temperature could be used in combination to influence the state of the MIT channel (606). Pressure could be used to compensate for manufacturing, doping, or other variations in the MIT channels (606). In one example, pressures could be generated by residual stresses between the layers as discussed below with respect to FIG. 6C.

To prevent an electrical shorting, the heater electrodes (624, 626) and the heater (620) are separated from the overlying left electrode (604) and the right electrode (608) and MIT channel material (606) by a thin dielectric layer (628). The dielectric layer (628) between the heater (620) and the MIT channel (606) can be constructed to provide sufficient electrical isolation while allowing good heat transfer between the heater (620) and the MIT channel (606). The electrical insulator (628) should be thick enough to prevent significant electrical conduction or electron tunneling and thin enough not to substantially impede thermal flow. A variety of materials could be used to create the electrical insulator. For example, nanoscale diamond films have very high electrical resistances and high thermal conductivity.

As discussed above, the entire structure may be supported by a substrate (622) which may also serve as a heat rejection reservoir to rapidly cool the MIT channel material (606) and allow it to revert back to its insulating state after the switching event is complete. The substrate (622) or cooling plate may be actively or passively cooled to maintain the temperature of the MIT switching device (630) within a range of allowable temperatures. For example, the range of allowable temperatures may be below the transition temperature of the MIT channel material (606) by a significant enough margin to allow heat to be transferred from the MIT channel material (606) to the substrate (622) in a timely manner. For example, the substrate (622) could be cooled by a passively cooled heat sink, a heat sink with forced convection, a Peltier cooler, fluidic cooling or other mechanism.

FIG. 6C describes one method of combining both pressure and temperature as extrinsic variables for controlling the state of an MIT channel. There are a number of additional methods which could also be used. For example, the MIT channel could be placed under residual stress or pressure as a result of a manufacturing or other process. This residual stress or pressure could be used to tune the metal-insulator transition temperature to a desired point. For example, a layer could be deposited over the MIT channel and then rapidly cooled. This layer would then contract over the MIT channel and exert a residual stress or pressure on the MIT channel. In another example, residual stress could be imparted to the MIT channel by the packaging of the MIT switching device. According to one embodiment, the MIT switching device could be pressed over a curved substrate. This would impart a residual stress throughout the device. In yet another example, crystalline MIT material may be deposited over a crystalline sublayer with a different lattice constant. This difference in lattice constants between two bonded and adjacent layers could produce the desired residual stress in the crystalline MIT material.

In some embodiments, the MIT devices may be used to sense environmental conditions. For example, an MIT sensor may be created which includes two electrodes which are separated by an MIT channel. The electrical conductivity of the MIT channel may be influenced by one or more environmental variables such as temperature, pressure, force, or flexure. These environmental variables can be sensed by measuring electrical resistance between the two electrodes. As used in the specification and appended claims, the term “environmental variable” refers to an independent parameter in the MIT device's physical surroundings. An environmental variable distinct from an extrinsic variable that is manipulated by a transducer that is part of the MIT device.

The MIT sensors may have a variety of configurations which are adapted to sense a desired environmental variable or combination of environmental variables. For example, an MIT pressure sensor may be directly compressed by environmental pressures. In another example, an MIT force sensor may be attached to a flexible substrate which changes shape in response to environmental forces. The pressures within MIT force sensor are altered by the change in shape of the substrate, leading to a change of resistance in the channel material.

Further, an extrinsic variable transducer may be used to fine tune the response of an MIT sensor. For example, if the MIT sensor is configured to sense environmental temperature, a pressure transducer may be used to adjust the temperature at which the MIT channel transitions from an insulating to a conducting state. Similarly, if the MIT sensor is configured to sense environmental pressure, a temperature transducer may be used to adjust the pressure at which the MIT channel in the sensor transitions from an insulating to a conducting state. Additionally or alternatively, the configuration and composition of the MIT channel material may be adjusted for more accurate sensing over a desired range. For example, the material type, number of defects, crystallinity, size, residual stress, or other characteristics of the MIT channel material could be selected so that the MIT channel exhibits varying electrical resistance through a desired pressure or temperature range.

In conclusion, the systems and methods above describe metal-insulator transition switching devices which leverage both lithography and nanoimprint technologies to create metal-insulator transition switching devices which can be used in both stackable and flexible applications. The switching devices do not require crystalline substrates and thus have broader application than silicon based transistors. These switching devices can be used in a broad range of applications, including flexible displays and multiplexer/demultiplexer circuits in planes of a multilayer memory. The MIT channel is inherently scalable because the metal-insulator transition is a bulk effect and consequently does not suffer from problems with dopant distributions on the nanoscale.

Further, the manufacturing process is scalable because the electrode intersections and channel do not require precise alignment. The simplicity of the manufacturing process can potentially lead to low cost implementation of the metal-insulator transition switching devices.

The preceding description has been presented only to illustrate and describe embodiments and examples of the principles described. This description is not intended to be exhaustive or to limit these principles to any precise form disclosed. Many modifications and variations are possible in light of the above teaching.

1-15. (canceled)

16. A metal-insulator transition switching device comprising:
a first electrode;
a second electrode;
a channel region separating the first electrode and the second electrode, the channel region comprising a bulk metal-insulator transition material.

17. The device of claim 16, further comprising a gate electrode operatively connected to the channel region and including an extrinsic variable transducer to change a state of the metal-insulator transition material from conducting to non-conducting and vice versa.

18. The device of claim 17, in which the transducer is a thermal transducer which is in thermal proximity to the channel region.

19. The device of claim 17, in which the transducer is a heater for increasing the temperature of the metal-insulator transition material such that at least a portion of the metal-insulator transition material changes from an insulator state to a metallic state.

20. The device of claim 17, in which the gate electrode comprises a higher electrical resistance portion interposed between two lower electrical resistance portions; the higher electrical resistance portion being disposed in proximity to the metal-insulator transition material such that when an electrical current is passed from the two lower electrical resistance portions through the higher electrical resistance portion, the higher electrical resistance portion heats the metal-insulator transition material and causes the metal-insulator transition material to change state.

21. The device of claim 20, in which the two lower electrical resistance portions and the higher electrical resistance portion are formed from the same material but have different cross sectional areas.

22. The device of claim 17, in which the transducer applies varying levels of pressure to the metal-insulator transition material.

23. The device of claim 22, in which the transducer is situated between the gate electrode and the channel region and comprises a piezoelectric material, and application of a voltage to the gate electrode causes the piezoelectric material to exert sufficient pressure on the channel region to cause a change in state of the metal-insulator transition material.

24. The device of claim 22, in which the metal-insulator transition material is sandwiched between two piezoelectric transducers.

25. The device of claim 17, in which the gate electrode comprises at least two extrinsic variable transducers.

26. The device of claim 17, in which the gate electrode comprises a thermal transducer and a pressure transducer, in which a combination of pressure and temperature is applied to cause a change in state of the metal-insulator transition material.

27. The device of claim 16, in which residual strains in the device exert force on the metal-insulator transition material to shift the transition temperature of the metal-insulator transition material.

28. The device of claim 16, in which a switching speed of the device is determined by capacitance and inductance of interconnection lines which attach the device to control circuitry.

29. The device of claim 16, further comprising a substrate that supports the device.

30. The device of claim 29, in which the substrate serves as a cooling plane and heat rejection reservoir.

31. The device of claim 16, in which the device is a sensor which detects at least one environmental variable.

32. A method for forming a metal-insulator transition switching device comprises:
depositing a layer of bulk metal-insulator transition material in between a first electrode and a second electrode, such that a first side of the metal-insulator transition material is in electrical contact with the first electrode and a second surface of the metal-insulator transition material is in electrical contact with the second electrode, the metal-insulator transition material forming a channel region; and
forming a gate electrode operatively connected to the channel region, the gate electrode comprising a transducer to change a state of the metal-insulator transition material from conducting to non-conducting and vice versa.

33. The method of claim 32, in which forming the gate electrode comprises depositing a piezoelectric transducer which is mechanically coupled to the metal-insulator transition material.

34. The method of claim 32, in which forming the gate electrode comprises forming a heating element that is thermally coupled to the metal-insulator transition material.

35. The method of claim 34, in which forming the heating element comprises forming the gate electrode with a reduced cross section portion, the reduced cross section portion being nearest the metal-insulator transition material.

36. The method of claim 32, further comprising:
forming the first electrode and the second electrode, the first electrode and second electrode being separated by a gap;
depositing an insulating dielectric blanket such that the insulating dielectric is not deposited in the gap; and
depositing a layer of metal-insulator transition material such that the metal-insulator transition material fills the gap between the first electrode and the second electrode.

37. The method of claim 36, further comprising:
depositing a layer of metal-insulator transition material into the gap;
depositing a thin dielectric layer over the metal-insulator transition material; and
depositing a conductive metal layer over the thin dielectric layer.

38. The method of claim 32, in which forming a gate electrode including a transducer comprises:
depositing a high resistance layer and a low resistance layer over the channel region; and
removing the low resistance layer over the metal-insulator transition material, such that electrical current is routed to the device through the low resistance layer and then passes through the high resistance layer to heat the metal-insulator transition material.

39. The method of claim 32, further comprising creating a residual stress in the channel region, the residual stress being calculated to alter the metal-insulator transition characteristics of the channel region.

40. The method of claim 39, in which the residual stress is created using one of: a lattice mismatch between the metal-insulator transition material and an adjacent layer, rapid cooling of a layer adjacent to the metal-insulator transition material, and the packaging of a device containing the metal-insulator transition switching device.
